(19) United States
(12) Patent Application Publication
(10) Pub. No.: US 2024/0234098 A1
(43) Pub. Date: Jul. 11, 2024

(54) GAS-FLOW-ENGINEERED PLASMA REACTOR FOR EFFICIENTLY PRODUCING FIXED NITROGEN PRODUCTS

(71) Applicant: NITRICITY INC., Fremont, CA (US)

(72) Inventors: John A. SCHWALBE, Santa Clara, CA (US); Joshua M. MCENANEY, Fremont, CA (US); Sreekumar CHOCKALINGAM, Fremont, CA (US); Sami KILANI, San Francisco, CA (US)

(21) Appl. No.: 18/410,958

(22) Filed: Jan. 11, 2024

Related U.S. Application Data
(60) Provisional application No. 63/438,398, filed on Jan. 11, 2023.

(51) Int. Cl. H01J 37/32

(52) U.S. Cl. CPC H01J 37/32449; H01J 37/32201; H01J 37/32522; H01J 2237/3321; H01J 2237/339

(57) ABSTRACT

Aspects of the present disclosure involve a plasma reactor system that includes a gas-flow-engineered reactor to more efficiently produce fixed nitrogen products. In some instances, the gas-flow-engineered reactor may include a gas vortex-inducing input mechanism and/or a quenching mechanism integrated or otherwise associated with the plasma reactor system.

### CROSS-REFERENCE TO RELATED APPLICATION

The present patent application is related to and claims priority under 35 U.S.C. § 119(e) from U.S. Provisional Patent Application No. 63/438,398 titled “Gas-Flow-Engineered Plasma Reactor for Efficiently Producing Fixed Nitrogen Products” filed on Jan. 11, 2023, the entire contents of what is hereby incorporated by reference for all purposes.

### TECHNICAL FIELD

Embodiments of the present invention generally relate to systems and methods for a plasma system for fixing nitrogen to be captured as fixed nitrogen products fixing nitrogen to be captured as fixed nitrogen products, and more specifically for a plasma-nitrogen fixation where the gaseous fixed nitrogen may be efficiently captured to form liquid and solid chemical and fertilizer products.

### BACKGROUND AND INTRODUCTION

Nitrogen-based fertilizers are used throughout the world for agricultural purposes. Product of nitrogen-based fertilizers may include one or more industrial processes to generate components of the fertilizer. The oxidation of nitrogen using a plasma is an important route to fixed nitrogen for use in such nitrogen-based fertilizers. This oxidation process occurs naturally in lightning storms and has been historically used on an industrial scale to create fertilizer in a process known as the Birkeland-Eyde process. In the Birkeland-Eyde process, thermal electrical arcs are created that react nitrogen with oxygen to create gas-phase oxidized-nitrogen species, which were then reacted with water to produce nitric acid. Nitric acid may be used as a source of nitrate for nitrogen-based fertilizers. However, the century-old Birkeland-Eyde Process suffers from poor nitrogen fixation efficiencies. Thermal arcs can also be destructive to electrodes particularly when not optimized for production of oxidized-nitrogen species.

Non-thermal plasmas have shown promise to improve energy efficiency of nitrogen fixation over that of thermal arcs. However, commercially available reactors today have not been designed for efficient nitrogen fixation. The ability to control gas flow dynamics within the reactor, in particular, can have a profound effect on the efficiency and yields of nitrogen fixation.

It is with these observations in mind, among others, that aspects of the present disclosure were conceived.

### SUMMARY

One aspect of the present disclosure relates to a plasma reactor for generating fixed-nitrogen products. The plasma reactor may include a microwave generator connected to a gas chamber, the microwave generator generating a plasma within the gas chamber and a gas-vortex-generating component connected to the gas chamber comprising one or more directional channels to direct input gas in a swirling motion into the gas chamber to generate a gaseous vortex within the chamber.

Another aspect of the present disclosure relates to a microwave-plasma reactor for generating fixed-nitrogen products comprising a microwave receiver configured with a gas chamber for generating a plasma and one or more quenching ports positioned in a sidewall of the gas chamber to provide a cooling stream of gases to quench reactions generated by the plasma. The microwave-plasma reactor may further include a gas-vortex-generating component connected to the gas chamber comprising one or more directional channels to direct input gas in a swirling motion into the gas chamber to generate a gaseous vortex within the gas chamber and a gas-tight connection between the gas chamber and the gas-vortex-generating component for containing reactant and product gases within the gas chamber.

Yet another aspect of the present disclosure relates to a method for producing fixed-nitrogen products by microwave plasma oxidation of nitrogen. The method may include the operations of producing a microwave plasma in a reactor containing a gas stream comprising nitrogen and oxygen, producing a high-velocity gas stream along the walls of the reactor, and producing oxidized nitrogenous species in the plasma reactor with the microwave plasma. The method may also include rapidly quenching the oxidized nitrogenous species in the plasma reactor using a cooling stream and removing the oxidized nitrogenous product from the plasma reactor for further processing and capture.

Another aspect of the present disclosure relates to a microwave-plasma reactor for generating fixed-nitrogen products comprising gas inlets for controlling the input gas flow and directionality, microwave radiation receiver cavity, a gas chamber for plasma production and propagation, a reaction quenching input, and an output fluidically connected to a pump for controlling reactor gas flow and pressure.

Another aspect of the present disclosure involves a microwave-plasma reactor for generating fixed-nitrogen products comprising a microwave generator operably coupled to a plasma chamber. The reactor further comprises a gas-vortex-generating component operably coupled with the chamber comprising one or more directional channels to direct input gas, such as nitrogen and oxygen (and/or air) in a rotational motion into the gas chamber to generate a gaseous vortex within the gas chamber, and which may also produce fixed nitrogen gaseous products from the plasma. The reactor may also include a quench channel operably coupled with the plasma chamber, the quench channel providing quench fluid into the plasma chamber to cool the plasma.

In some aspects, the gas-vortex-generating component comprises two or more opposing inputs, each with groove channels comprising a pitch angle between 15 degrees and 65 degrees from a top of the gas-vortex-generating component. In some aspects, the gas-vortex-generating component directional channels are adjacent to an outer surface of the gas-vortex-generating component or are adjacent to an inner surface of the gas-vortex-generating component.

In another aspects, the present disclosure involves a microwave-plasma reactor for generating fixed-nitrogen products comprising: a microwave generator operably coupled with a plasma chamber; a gas-vortex-generating component connected to the plasma chamber comprising one or more directional channels to direct input gas in a rotational motion into the plasma chamber to generate a gaseous vortex within the gas chamber wherein microwave energy ignites a plasma from the gaseous vortex; and one or more quenching ports operably coupled with the gas chamber to provide a cooling stream of gas to quench reactions generated by the plasma.

The one or more quenching ports may be positioned to inject a cooling stream at or proceeding a point of plasma ignition in the plasma chamber and may comprise two or more opposing quenching ports in a sidewall of the plasma chamber. The opposing one or more quenching ports may be configured at an angle between 10 degrees and 170 degrees with an axis of the plasma chamber. The quenching ports may also be laterally offset and/or oriented to generate a vortex of quenching gases within the plasma chamber. The orientation may cause the generated vortex to be concurrent to the swirling motion generated by the gas-vortex-generating component or countercurrent to the swirling motion generated by the gas-vortex-generating component.

For cooling/quenching, the gas chamber may comprise a reactor portion with a first diameter and a quenching portion with a second diameter larger than the first diameter.

The reactor may include a metal sleeve surrounding the gas chamber and comprising sleeve quenching ports positioned in a sidewall of the metal sleeve corresponding to the quenching ports of the gas chamber, the metal sleeve defining an air gap between an outer surface of the gas chamber and an inner surface of the metal sleeve.

Aspects of the present disclosure also involve a method for producing fixed-nitrogen products by microwave plasma oxidation of nitrogen, the method comprising:
producing a microwave plasma in a plasma reactor containing a gas stream comprising nitrogen and oxygen;
producing a rotational gas stream along a wall of the plasma reactor;
producing oxidized nitrogenous species in the plasma reactor with the microwave plasma through a conversion of the nitrogen and the oxygen; and
quenching the oxidized nitrogenous species in the plasma reactor using a cooling stream.

The gas stream may be injected in a rotational pattern along a cylindrical wall of the plasma reactor. The oxidized nitrogenous species may comprise nitric oxide, nitrogen dioxide, nitrous oxide, dinitrogen dioxide, nitric acid, and nitrous acid. The concentration of nitrogen in the gas stream is between about 5% to about 85% and wherein a concentration of oxygen in the gas stream is between about 5% to about 85%.

The cooling stream may comprise a high-velocity gas surrounding a high-turbulent viscosity gas. The cooling stream gas may be a different composition than the gas stream. The cooling stream may comprise a quenching liquid. The cooling stream may be injected to cooperate with a plasma vortex comprising the oxidized nitrogenous species. The cooling stream may also be injected to be counter or otherwise disrupt a plasma vortex comprising the oxidized nitrogenous species.

These and other aspects of the present disclosure are described in further detail below.

### BRIEF DESCRIPTION OF THE DRAWINGS

The foregoing and other objects, features, and advantages of the present disclosure set forth herein should be apparent from the following description of embodiments of those inventive concepts, as illustrated in the accompanying drawings. The drawings depict only typical embodiments of the present disclosure and, therefore, are not to be considered limiting in scope.

FIG. 1 is a diagram of a plasma reactor system for producing plasma that includes gas-flow control and quenching mechanisms.

FIG. 2 a flowchart of a method for operating a gas-flow-engineered microwave reactor to produce fixed-nitrogen products.

FIG. 3A is a diagram illustrating a first embodiment of a gas vortex input mechanism for controlling the gas input into a plasma reactor system for improved nitrogen fixation.

FIG. 3B is a cross-section diagram illustrating a second embodiment of a gas vortex input mechanism for controlling the gas input into a plasma reactor system for improved nitrogen fixation.

FIG. 4A is a diagram illustrating a first embodiment of a gas-flow quenching mechanism for altering the gas flow directionality, positional velocity, and regions of viscosity to rapidly quench fixed nitrogen products from the hot plasma.

FIG. 4B is a top view of the gas-flow quenching mechanism for altering the gas flow directionality of FIG. 4A.

FIG. 4C is a diagram illustrating a second embodiment of a gas-flow quenching mechanism for altering the gas flow directionality, positional velocity, and regions of viscosity to rapidly quench fixed nitrogen products from the hot plasma.

FIG. 5 is a diagram illustrating a first outer sleeve for a plasma chamber of the plasma reactor system.

FIG. 6 is a diagram illustrating a second outer sleeve for a plasma tube of the plasma reactor system.

FIG. 7A is a diagram illustrating a first example of a plasma chamber of the plasma reactor system including an expansion portion for quenching a plasma reaction for improved fixed nitrogen products generation.

FIG. 7B is a diagram illustrating a second example of a plasma chamber of the plasma reactor system including an expansion portion for quenching a plasma reaction for improved fixed nitrogen products generation.

FIG. 8 is a block diagram illustrating a microwave-based plasma reactor system.

FIG. 9 depicts graphs illustrating the effect of vortex angle on efficiency and a total nitrogen concentration of the plasma reactor system at various air flow rates.

### DETAILED DESCRIPTION

Aspects of the present disclosure involve a plasma reactor system that includes a gas-flow-engineered reactor to efficiently produce fixed nitrogen products. In some instances, the gas-flow-engineered reactor may include a gas vortex-inducing input mechanism and/or a quenching mechanism integrated or otherwise associated with the plasma reactor system. Generally, the gas vortex-inducing input mechanism may control a gas input to the plasma reactor, which may include defining/controlling directional and/or positional velocity of the gas input, to generate a vortex action within a plasma chamber. As the input gas to the plasma reactor may take on a vortex movement within the plasma chamber, some or all of an ignited plasma within the chamber from the input gas may take on a similar vortex movement. A quenching mechanism may also be associated with the plasma reactor to quench the plasma to quickly reduce the temperature of the plasma reaction occurring within the chamber. Rapid reduction of the plasma temperature through quenching of the plasma reaction may increase the conversion efficiency of the plasma reactor by limiting back reactions that may occur within the plasma. The gas input mechanism and quenching mechanism may in general optimize the resonance time of the plasma to within a particular temperature and maximize conversion of the input gas to the fixed nitrogen, while reducing and possibly minimizing any inefficient back reactions. Provided herein are examples of such gas-flow-engineered reactor components and methods with the features, materials, and properties to overcome the challenges of inefficient generation of fixed nitrogen products.

In some implementations, the plasma reactor system may include a microwave plasma reactor including a microwave plasma gas chamber designed to contain a microwave generated plasma into which nitrogen and oxygen may be fed to produce oxidized nitrogen species. Oxidized nitrogen species may include nitric oxide, nitrogen dioxide, nitrous oxide, dinitrogen dioxide, nitric acid, nitrous acid, among other oxygen-containing nitrogen compounds. Power is provided to a microwave generator, which generates microwaves, which may be at 915 MHZ, sufficient to ignite and sustain a plasma containing nitrogen and oxygen in the microwave plasma gas chamber.

The gas-flow-engineering-specific advancements discussed herein may be utilized in conjunction with such a microwave plasma gas system. For example, the gas vortex-inducing mechanism and/or the quenching mechanism may be operably associated with the microwave plasma gas chamber to protect the components of the plasma reactor system and/or improve the efficiency of the microwave plasma reactor system. Additional advancements may also be included, such as a metal sleeve oriented around the plasma chamber. In such an example, the plasma chamber may include an inner chamber, which in some instances may be an inner sleeve, and an outer sleeve, which in some instances may define an enclosure except for the inputs and outputs. The inner chamber may be optimized for containing the plasma, heat transfer properties and otherwise whereas the outer sleeve may be optimized for containing high pressures and supplementing the inner chamber, which may not handle high pressures by itself, allow for heavy flanges and connection points to other parts of the system, and provide a support structure for any heat transfer mechanism or medium (cooling coils for coolant fluid, air or gas flow, etc.)_provided between the sleeve and the inner chamber. Supporting the inner chamber within a sleeve may also allow for and support expansion of the inner chamber, particularly when associated with high heat, rapid cooling through quenching, and high temperature differentials from the same. These advancements, among others, may be beneficial to the microwave plasma reactor for efficiently producing nitric acid and nitrate fertilizers, in some implementations.

After nitrogen products are formed, various methods may be used to concentrate or dry them, such as distillation tower and a rotary drying drum, such that the products may be used for forming liquid and solid chemical and fertilizer products, among other things.

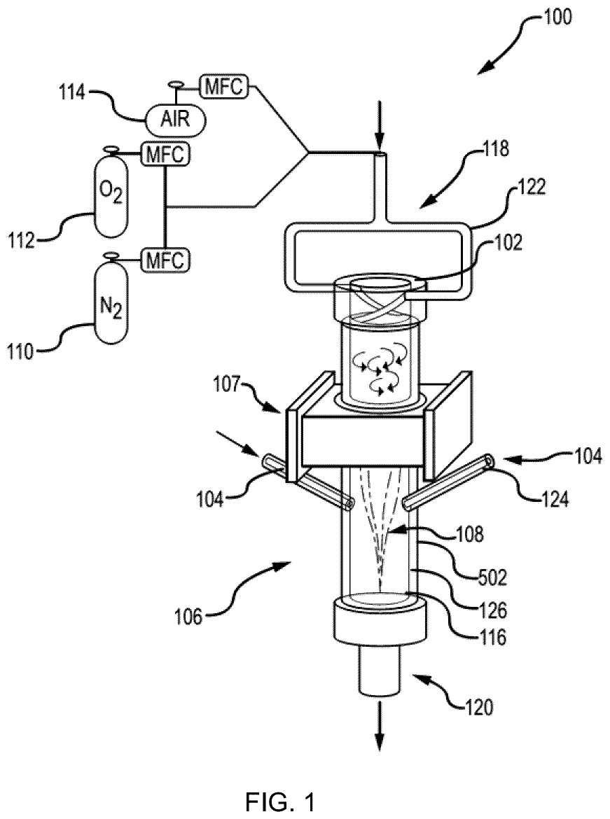

FIG. 1 is a diagram of a plasma reactor system 100 including a vortex flow assembly 102 and a quenching assembly 104 to improve the efficiency of generating fixed nitrogen products by the plasma system. In general, system 100 is a plasma-based system in which a reactor 106 generates a plasma 108 from nitrogen 110 and oxygen 112 gas (or, alternatively or additionally air 114) within a plasma chamber 116, the plasma generating a combination of ionized nitrogen and oxygen species. In the example illustrated in FIG. 1, the plasma reactor 106 receives nitrogen gas 110, oxygen gas 112, and/or air 114 through a gas input mechanism 118. The gas input mechanism 118 may be capable of isolating the oxygen and the nitrogen gas from the air, in some instances where air (e.g., air from the environment) is a source of oxygen and/or nitrogen. For example, the oxygen and nitrogen may be isolated from the air through a pressure swing absorber, membrane separator, a cryogenic air separation system, or any other air or gas separation system. An energy source 107 provides thermal, electrical, electromagnetic, or other energy to the reactor 116 for generating the plasma/ionized gas species from the nitrogen and oxygen provided by gas input mechanism 118. In one implementation, the plasma energy source 107 includes a magnetron and waveguide to generate and direct energy to generate a plasma 108 within the reactor chamber 116 from the nitrogen 110 and oxygen 112 gas input from gas input mechanism 118.

The nitrogen-oxygen plasma 108 oxidizes within the plasma chamber 116 to form a product gas stream including oxidized nitrogen species, which may exit the chamber at an outlet collar 120 located at the bottom of the plasma chamber. The plasma chamber 116 may connect to the outlet collar 120 through one or more gas-tight seals. Although not illustrated in FIG. 1, an absorption unit may be in communication with the outlet collar 120 of plasma chamber 116 to receive the product gas stream and produce fixed-nitrogen products from the product gas stream. Examples of absorption units are provided in U.S. patent application Ser. No. 17/240,768, which is incorporated herein by reference.

Plasma with sustained ionization generally occurs at high temperatures, often around 3,000° C. or higher. Such temperatures, however, may damage the interior of the plasma chamber 116. For example, many lower temperature plasma chambers are constructed from a dielectric material, such as quartz glass, which has a melting point of around 1,715° C. In addition, back reactions may occur within the plasma 108 at its highest temperatures that reverse the desired conversion of the nitrogen 110 and oxygen 112 gas into the combination of ionized nitrogen and oxygen species. As such, mechanisms may be incorporated into the plasma reactor system 100 to protect the plasma chamber 116, reduce the back reactions that may occur within the plasma 108, and generally increase the efficiency the of fixed-nitrogen products from the product gas stream of the plasma reactor system 100.

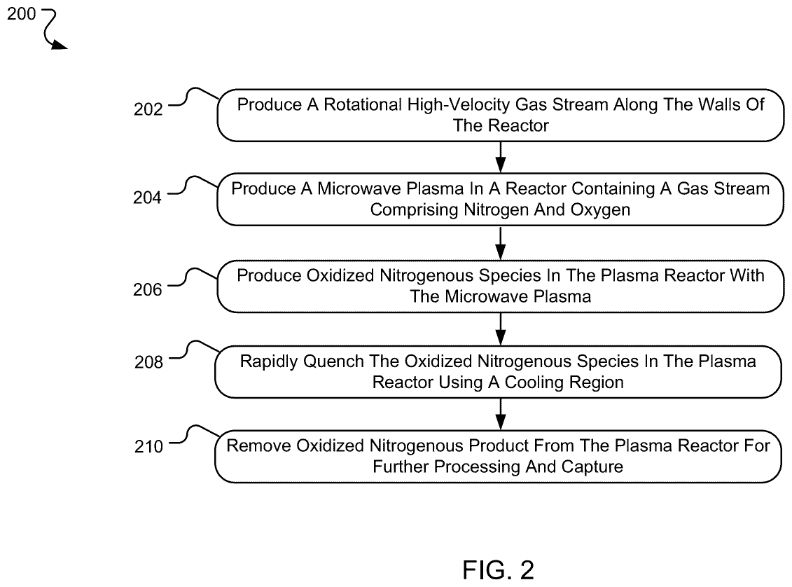

FIG. 2 a flowchart of a method 200 for operating a gas-flow-engineered microwave reactor to produce fixed-nitrogen products, the reactor including components and/or features to improve the efficiency in the output production. At operation 202, a gas stream, which may in some embodiments be a high-velocity gas stream, of input gas comprising nitrogen gas 110 and oxygen gas 112, and/or air as discussed herein, may be generated along the walls of a gas-flow engineered input mechanism 118 to a plasma chamber 116. The nature of the vortex and gas input locations makes the outer vortexing gas (the gas relatively closer to and at the cylindrical inner wall of the chamber) a higher velocity relative to the inner vortexing gas (the gas relatively closer to and at a longitudinal center line of the chamber), which has the effect of constraining the plasma phase to the hotter inner portion of the tube or container. In such an arrangement, the outer gas is also relatively colder and the older outer vortexing gas quenches the inner plasma reacting gas.

Various aspects of the overall system may be tuned through the presence of the plasma vortex and quenching including microwave power, plasma chamber diameter and length, and operating temperature. For example, relatively increasing the velocity of the quench gas, the system can be tuned to provide a relatively more constrained, smaller plasma with a faster quench. Tuning this property may have an impact on energy efficiency. Generally, so long as the plasma reacting gas reaches a high enough reaction temperature, a relatively faster quench provided from injecting quench gas at a higher velocity, may be beneficial to optimize the plasma gas reaction and minimize any back reactions. Flow rates and velocities may depend on the scale of the reactor among other attributes. Besides quench gas velocity, the system may also be tuned for the angle of quench channel/quench input gas to adjust how often the quench gas flows around the vortex, relative to the length of the plasma chamber. It should be recognized that the gas will intermingle with the plasma and it does not strictly flow around the plasma. Generally, a shallower input angle will create a tighter, more compressed, quench vortex and greater circulations around the plasma whereas a steeper input angle will create a looser, less compressed, quench vortex with lesser circulations around the plasma.

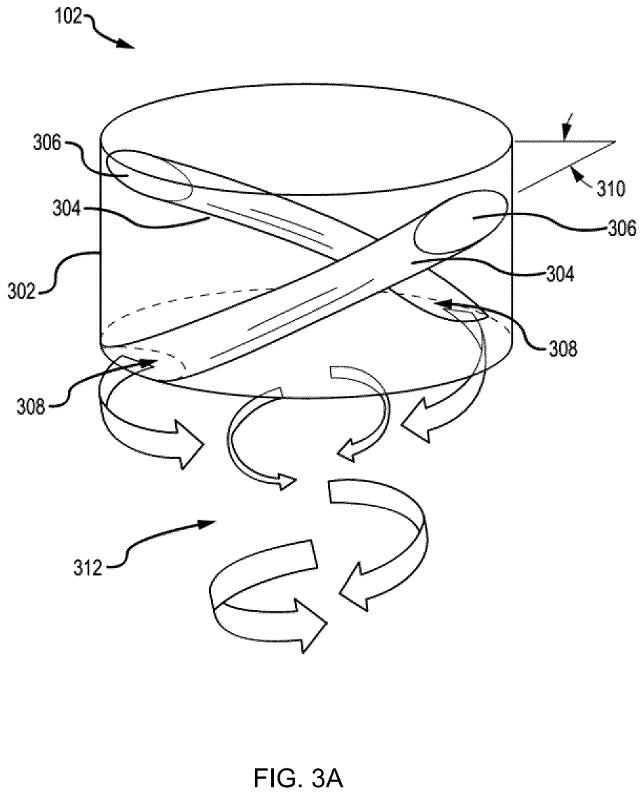

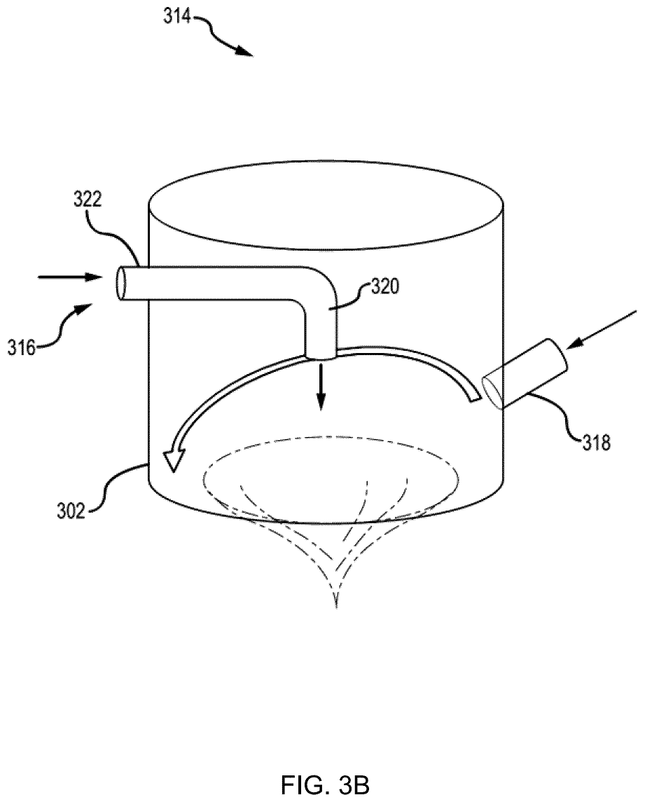

Using the system 100 of FIG. 1 as an example, the input gas may be introduced into the plasma chamber 116 via a gas vortex input mechanism 102 for controlling the directionality and positional velocity of the gas input for improved nitrogen fixation. The gas is provided into the chamber to form a vortex of flowing gas. In some examples, the vortex is formed prior to the plasma chamber and prior to ignition as a plasma. In other examples, the vortex may be formed in the plasma chamber. Examples of a gas vortex input mechanism are illustrated in greater detail in FIG. 3A and elsewhere. In one example, the gas vortex input mechanism 102 includes a cylindrically-shaped collar 302 that mates or otherwise connects to a top portion of the plasma chamber 116. In some instances, the inner circumference of the cylindrically-shaped collar 302 may be the same as the inner circumference of the cylindrically-shaped plasma chamber 116. In other instances, the circumference of the cylindrically-shaped collar 302 of the gas vortex input mechanism 102 may be greater or lesser than the circumference of the plasma chamber 116. The cylindrically-shaped collar 302 may be constructed with the same dielectric material as the plasma chamber 116, a different dielectric material, or any other material for receiving input gas and transferring the gas to the plasma chamber 116 in a controlled manner. In some instances, a quartz sleeve may be present at the interface between the collar and the plasma chamber, with the quartz sleeve providing a dielectrically consistent transition area into the plasma chamber and at the opening to the plasma chamber.

As shown in FIGS. 1 and 3A, one or more directional channels, which may be tubes 304, may be adjacent to, and follow the shape of, the sides of the cylindrically-shaped collar 302 of the gas vortex input mechanism 102. The collar 302 of FIGS. 1 and 2 illustrate two such channels 304, although more or fewer channels may be included. Each directional channel 304 may include a gas input port 306 and a gas exit port 308 and may include a curved body portion between the input port and the exit port that contours to the shape of the cylindrically-shaped collar 302. The channel (or channels) and the exit port into the collar direct the gas to form a gas vortex within the collar and which also transitions into and forms in the plasma chamber. In place of tubular members, the channel, or some portion thereof, may be formed in the inner cylindrical wall of the collar in the form of helical grooves, like formed by internal threads of a nut. The helical grooves providing channels in which the gas flow vortex is formed where the gas exits the helical groove structure. For example, an exit port may be formed in the collar with a gas inlet (e.g., flexible resilient hosing) coupled at an inlet port. It should be recognized that the exit port orientation, which may or may not also include the channel orientation, directs the gas into the helical groove structure of the collar to form a vortex. The exit port may or may not include a nozzle to provide direction and or increased pressure and velocity to the gas relative to the input of the gas. The channel and exit port may be oriented to direct the gas along the side walls of the collar, into the space between of the collar, and more or less toward the plasma chamber to which the collar is attached with each tailorable to form a vortex shape based on the size of the collar, the size of the plasma chamber, the gas velocity, and other factors. The channels may further be tapered from the upper input, with a greater depth, to a lower output have a lesser depth which may merge with the inner side wall of the collar at the sleeve to form the vortex within the sleeve. Tapering may also occur in the sidewalls of the channel. In either event, depending on the system and gas input characteristics, tapering may be used to accelerate and alter the direction and pressure as the gas exits into the collar or plasma chamber. In one example, the channel refers to the area between the gas input and gas exit. The channel may simply open into the collar or chamber, in which case the open end of the channel is the exit port. The channel may be partially or completely integrated in the collar. In some instances, some or all of the channel may be provided by a tube or hose. In some examples, the channels are generally helically shaped. As noted, the output into the chamber may be spaced to avoid turbulence that might occur if the channel outputs are positioned too closely or intersect. The channels 304 may be interior or exterior to the cylindrically-shaped collar 302. To form a closed channel with the collar, channels may be defined in the body portion with a sleeve insert that covers the channels.

In general and referring to FIG. 1, one or more gas input pipes 122 may receive the nitrogen gas 110, oxygen gas 112, and/or air 114 and provide the gas to the one or more input ports 306 of the directional channels 304. The directional channels 304 may also include portions that do not contour to the shape of the cylindrically-shaped collar 302, such as angled portions, vertical portions, and/or horizontal portions.

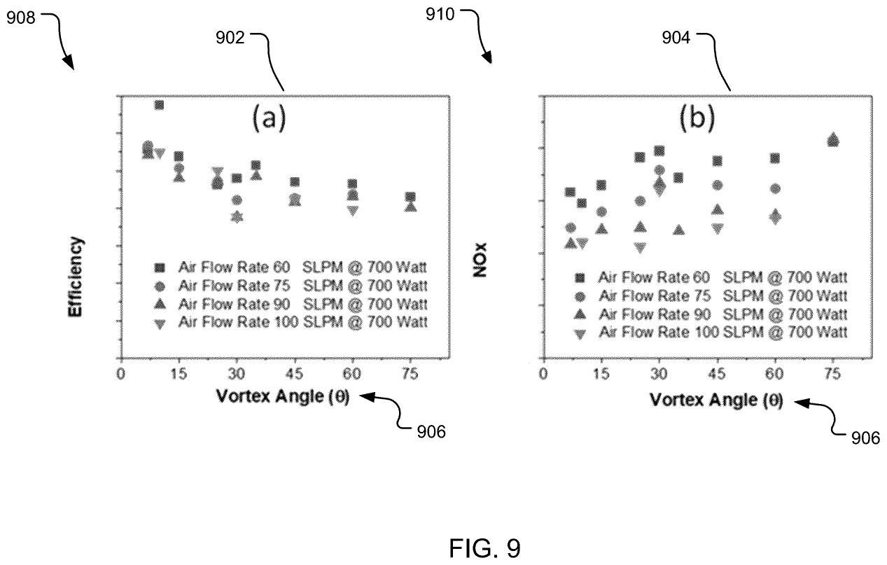

Generally, the directional channels 304 of the gas vortex input mechanism 102, and more particularly the exit ports 308 of the directional channels, direct the input gas to swirl around the interior of the cylindrically-shaped collar 302, generating a vortex of input gas 312 within the collar and in an upper portion of the plasma chamber 116. If more than one channel is included, the channels may be symmetrical oriented around the circumference of the collar such that each channel directs gas into the collar to cooperatively form a vortex. In one example, the channels are evenly spaced such that two channels are 180 degrees separated (with reference to the respective exit ports), three channels are 120 degrees separated, and four channels are separated 90 degrees, in various possible examples. The outputs inject the gas into the tube at an angle and along the tube walls to form a helical vortex flow within any or all of the tubular gas processing members (e.g., the collar, the plasma chamber itself, and any possible tubular member (e.g., a sleeve connecting the collar to the plasma chamber). In reference to an embodiment including a collar, upon exiting the direction channels 304, the input gas may continue along the inner surface of the cylindrically-shaped collar 302 in a helical form. It should be recognized that the plasma chamber itself may include a collar region, which may be an integral portion of the plasma chamber. In one example, such a collar region may be positioned before where the plasma is formed. The directional channels 304 may be angled within the cylindrically-shaped collar 302 at a vortex angle 310 (also discussed relative to FIG. 9), defined from a perpendicular plane through the cylindrically-shaped collar and a vector through the center of the corresponding input port. The vortex angle 310 may be associated with a velocity of vortex 312 of input gases within the gas vortex input mechanism 102. For example, a relatively shallower vortex angle 310 (an angle less than shown in FIG. 3A) may generate a vortex 312 of flowing gases of a relatively higher velocity in comparison to a steeper vortex angle (an angle greater than shown in FIG. 3A). In addition, a steeper vortex angle 310 may push the input gases 312 further into the plasma chamber 116 in comparison to a shallower vortex angle. In general, the vortex angle 310 of the directional channels 304 may range from a 10 to an 80-degree angle. In one various implementations, the vortex angle 310 may range from 15 degrees to 65 degrees.

FIG. 3B is a cross-section diagram illustrating a second embodiment of a gas vortex input mechanism for controlling the gas input into a plasma reactor system for improved nitrogen fixation. This embodiment of the gas vortex input mechanism 314 may include the same or similar cylindrically-shaped collar 302 as described above. However, in this example, gases may be injected into the interior of the collar 302 through a center channel 316 and a side channel 318. More particularly, the center channel 316 may include a substantially vertical channel 320 with an output port through which gas may be injected along a center axis of the collar and which may also be a center axis of a connected plasma chamber. As shown the gas is injected downwardly and vertically into the collar 320 at or near the center of the collar (either in an up or down direction). This arrangement is for a system where the collar is positioned above the plasma chamber, and the system is arranged vertically. Such a system may be preferable is some embodiments so that gravity does not distort the vortex shape, and gravity cooperates with the gas flow into and through the system. In some instances, the center channel 316 may also include a generally horizontal feeder channel 322 for transmission of the center gas to the vertical channel 320. Regardless, gas may be fed to the vertical channel 320 for direct injection to the center of the cylindrically-shaped collar 302.

In addition to the center channel 316, a directional channel 318 (or channels) may inject a second gas stream into the channel area to form a vortex. The channel (or channels) may be similar to the various possible embodiments discussed above. The directional channel 318 may therefore be angled relative to the collar 302 such that gas is injected into the collar at both a vertical and horizontal angle, and at angle relative to the inner collar area (e.g., more or less toward the center axis along which the first gas stream flows). The position of the directional channel 318 may be such that the gas injected through the directional channel may swirl around the interior of the cylindrically-shaped collar 302, generating a vortex of input gas within the collar and in an upper portion of the plasma chamber 116. The injected gas through both the direction channel 318 and the center channel 316 may aid in generating the vortex shape of the plasma within the plasma chamber 116.

As mentioned, the gas vortex input mechanism 102 may cause the input gases to controllably flow around the interior of the plasma chamber 116 as the gas travels from a first side, where gas enters the chamber (e.g., the top of the chamber in the orientation shown) to a second side of the chamber where plasma processed material exits the chamber (e.g., the bottom of the chamber in the orientation shown). Returning to the method 200 of FIG. 2, a non-thermal plasma, such as one generated from microwave energy, may be produced in the reactor that includes the gas input stream of air, and/or nitrogen and oxygen at operation 204. For example, the energy source 107 may generate a plasma 108 from the helical flow of nitrogen 110 and oxygen 112 gas received from gas input mechanism 118. Although described herein using a microwave energy source 108, it should be appreciated that other energy sources, such radio frequency energy, may also be utilized with the mechanisms and systems described. At operation 206, an oxidized nitrogenous species is produced within the plasma chamber 116 from the input gas provided through the gas vortex input mechanism 102. As the vortex input mechanism 102 causes the input gas introduced into the plasma chamber 116 to form a vortex, the plasma 108 generated in the reactor chamber 116 may similarly take a vortex shape or form. In particular, the directional channels 304 and cylindrically-shaped input collar 302 generate a vortex of the input gases within the chamber 116. The input gases may continue to form the vortex upon plasma ignition, swirling the vortex about a center axis line through the reactor chamber 116. Generating a vortex of plasma 108 may prevent the plasma from damaging the reactor chamber 116. For example, the vortex movement of the plasma 108 orients the highest plasma temperatures to be at and relatively near a center line of the vortex (and thereby about the center line of the reactor chamber 116) and the coolest temperature nearer the inner surface of the plasma chamber 116. As sustained and relatively high temperatures may damage the dielectric material of the reactor chamber 116, the generated vortex form of the plasma 108 may prevent damage to the inner surface of the reactor chamber by keeping the highest temperatures of the plasma at or near the center line of the chamber, and away from the plasma chamber wall. The vortex plasma 108 may therefore be safely maintained within the chamber 116 to generate the fixed nitrogen product.

In addition, back reactions may occur within the plasma 108 particularly at relatively high temperatures. Generally, back reactions reverse the conversion of the nitrogen 110 and oxygen 112 gas into the desired combination of ionized nitrogen and oxygen species. In other words, the longer the plasma 108 is maintained at its highest temperature, the less efficient the input gases may be converted to ionized nitrogen and oxygen species. To improve the overall efficiency of the conversion, a quenching assembly 104 may be incorporated with the plasma reactor 106 to, in operation 208, rapidly reduce the temperature of the plasma vortex 108 and reduce or prevent the back reactions that may occur within the plasma. In general, the quenching of the plasma 108 may occur at a level within the reaction chamber 116 below the point of highest temperature of the plasma. By first allowing the plasma 108 to occur at the high temperature, followed by a rapid quenching of the temperature of the plasma below the point of highest temperature, an efficient conversion of the input gases into the combination of ionized nitrogen and oxygen species may occur.

While a quench assembly may be used to limit back reactions and improve efficiency, the plasma vortex may also be used, alone or in combination, with quenching (also through the expansion chamber discussed below) to improve efficiency and reduce back reactions. A relatively faster flow of the vortex results in better efficiency up to a limit and thus vortex flow and the speed and various attributes of the same may be tailored to optimize performance. Additionally, with relatively slower vortex feeds, efficiency may be improved by increasing gas flow, providing another variable by which to optimize performance.

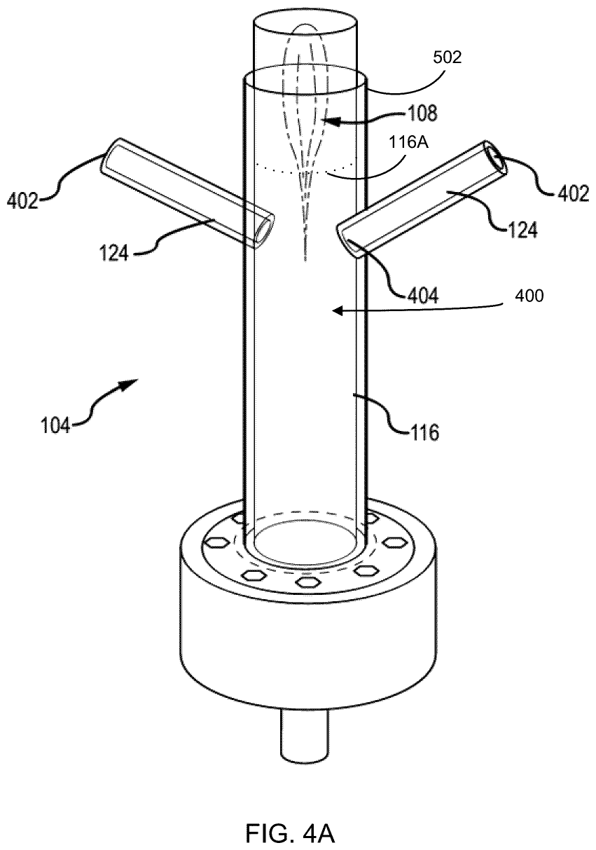

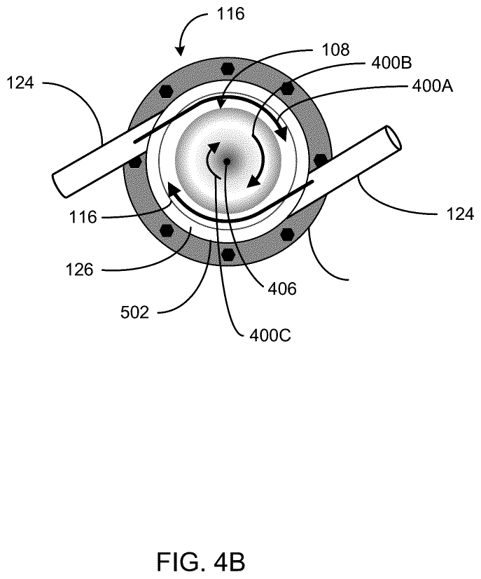

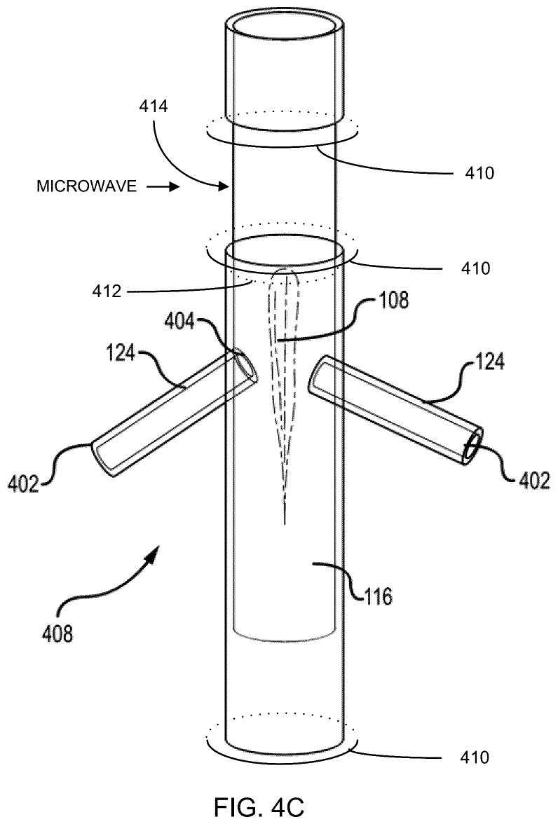

One particular implementation of a quenching assembly 104 is illustrated in FIGS. 1 and 4A. Here, the chamber 116 may be quartz extending the length of the chamber and supported within a sleeve 502 as discussed herein. Alternatively, which may also be the case with other arrangements discussed herein, the quartz portion may not extend the entire length and may instead extend only partially along the length of the chamber, e.g., to line 116A. The quartz region may be proximate the plasma ignition area. In this example, the quenching assembly 104 may include one or more quenching channels 124, which may comprise a tube fluidly coupled with the interior of the plasma chamber 116, and through which one or more quenching gases may be injected into the chamber.

The injection of such quenching gases may introduce additional surface molecules across the plasma vortex 108 maintained within the chamber 116 to cool the temperature of portions of the plasma. In various examples, the quenching gas is a lower temperature than the plasma. In some instances, the quenching gas may be provided at “room” temperature, and not actively controlled. In some instances, the gas temperature may be controlled at some process temperature. The quenching gas may include some combination of the input gases discussed above or may include different gases. In some instances, the quenching gases may comprise air, oxygen, nitrogen, oxygen-rich air, and the like. The injection of quenching gas or liquid, which may be referred to as cooling streams, may comprise a high-velocity gas surrounding a high-turbulent viscosity gas. The cooling stream may include a gas with a different composition than the input gas stream. Additionally or alternatively, the cooling stream may include an oxygen-rich gas stream to quench and further oxidize the oxidized nitrogenous species.

In some specific examples, the system creates an internal region of high turbulent viscosity in the vortex surrounded by an outer region of high velocity (at the outer radius of the chamber) for quenching. By way of explanation, if the gas becomes too trapped in the internal turbulent viscosity region because that region is too large, one can heat the molecules up for too long and lose efficiency. However, in an efficient reactor, this region at least had higher turbulent viscosity than the surrounding region which had much higher relative velocity. Controlling the input velocity will have an impact on regions relatively since the flow will slow toward the center, and can be tailored to optimize efficiency. While velocities will depend on a number of factors, an example of a high velocity of the outer vortex is over 5000 linear feet per minute for a reactor gas flow of 150 Ipm (probably over 10,000). The velocity may be higher if the flow is higher.

In addition, a liquid, such as water, may be injected into the plasma chamber 116 through the quenching channels. The injection of the quenching gases and/or liquids (e.g., water in a stream or mist, which may also provide evaporative cooling) may quench the reactions and allow the plasma reactor system 100 to capture a larger concentration of the product before the onset of inefficient back reactions. Generally, the plasma chamber includes one or more ports through which a cooling stream may be injected into the plasma chamber to quench the plasma (rapidly cool). In some form, a valve or other such structure is provided to couple a source of the cooling stream. For example, a cooling stream hose or pipe may be provided and connected at a valve whereby a quenching gas or liquid is provided. While illustrated in FIG. 1 as a tube 124 connected to the plasma chamber, the quenching channel may comprise a port or other connection point, which may be tubular, to the plasma chamber. The connection provides an input location for inputting quenching gas into the chamber. In one possible example, the quenching channel includes a quartz tube with quartz tube inputs attached at various points of the tube, which may be fitted with gas connections, metal to quartz converters with gaskets. In some examples, a tubular quartz segment (or other dielectric material segment) may be provided at the input to the chamber to hold the plasma ignition. The quartz segment may be connected directly to the chamber or may be provided as an inner sleeve of a stainless steel or other suitable tubular member carrying quenching gas, with the stainless tubular member connected to the outer sleeve and the inner quartz member providing an interface to the inner quartz chamber. Regardless of the configuration, the quenching channel (or channels) provides quenching gas into the chamber.

One or more cooling streams may be provided. These streams may be evenly separated, e.g., two streams separated by 180 degrees, three streams separated by 120 degrees, or four streams separated by 90 degrees. The streams may also be arranged and injected at various possible positions relative to the plasma in the chamber, e.g., closer or further from the base of the plasma where it is ignited. Additionally, different streams may be provided along the plasma, e.g., a stream or streams toward the base and a stream or streams further along the plasma. At different positions, different gases and gas velocities may also be provided.

The quenching stream may be injected radially into the plasma chamber. In some embodiments, the quenching stream is provided into the chamber at some angle, which may be to cooperate or interfere with the plasma vortex. For example, the quenching channels 124 are angled with respect to the sidewalls of the plasma chamber 116 and include an input port through which one or more quenching gases may be introduced and an exit port 404 located adjacent to or within the interior of the plasma chamber 116. The quenching channels 124 may also be laterally angled to oppose or coincide with the swirl direction of the plasma vortex 108. For example, a plurality of quenching channels 124 may be angled to inject quenching gas in a clockwise or counterclockwise direction within the circular plasma chamber 116. The angle of the quenching channels 124 may be oriented to inject the quenching gas concurrent with the direction of the plasma vortex 108 (308) such that the injected quenching gas rotates in the same direction as the plasma vortex (as directed through the gas vortex input mechanism 102 described above). For purposes of example, FIG. 4A is illustrated with the quench gas injected coinciding with the plasma vortex and FIG. 4C is illustrated with the quench gas injected opposing the vortex direction. The arrangement of FIG. 4A does not cause turbulence or minimizes turbulence and disruption of the plasma shape. In other instances, like illustrated in FIG. 4C the quenching channels 124 may be oriented to inject the quenching gas countercurrent to the direction of the plasma vortex 108 such that the injected quenching gas rotate in an opposite direction as the plasma vortex. An opposing direction of the quenching gas may be used to rapidly cool the temperature of the plasma vortex 108, with the turbulence and deconstruction of the plasma shape rapidly mixing the plasma and injected material. In general, different angles, quenching channel diameters, orientations, gas and/or liquid injection velocity and volume, and the like, of the quenching mechanism 104 may be used to rapidly cool the plasma vortex 108 and limit or eliminate back reactions within the plasma, with various such angles and arrangements to optimize conditions in various possible implementations.

FIG. 4B illustrates a top view of the reactor of FIG. 4A including the quenching channels 124. As can be seen, the quench channels in this view are tangential to the radius of the cylindrical chamber. The view is representative and is meant to illustrate the orientation of the quench channels to form a quenching gas vortex 400 where the outermost portion 400A rotates at a higher velocity than the portions 400B, 400C with the velocity of the vortex slowing toward the longitudinal centerline 406 of the chamber, about which the vortex rotates.

FIG. 4C illustrates a second implementation of a gas-flow quenching mechanism 408 for rapidly quenching the hot plasma 108. The components and/or operation of the second implementation 408 are similar to that described above. For example, the second implementation may include one or more quenching channels 124 extending into the plasma chamber 116, with each channel including an input port 402 for receiving a quenching gas and an output port 404 for injecting the quenching gas into the plasma chamber. In this implementation, however, the quenching channels 124 may be connected to the plasma chamber 116 to inject quenching gas in opposition to the flow direction of the plasma. With the orientation of the system illustrated in FIG. 4B, the plasma is ignited toward the top of the FIG. and the gas flow is downward. The quenching gas includes an upward oriented aspect against the gas and plasma flow. Further, the quenching channels 124 may direct the quenching gas at the plasma 108 near the center area of the plasma vortex, or the region of highest temperature of the plasma. In this manner, the quenching gas may cool the plasma vortex 108 at the hottest point to reduce the temperature of the reactions of the plasma to reduce the potential for inefficient back reactions. Also similar to above, the quenching channels 124 may be oriented to circulate the quenching gas concurrent to the plasma vortex 108 or countercurrent to the vortex direction (as shown in FIG. 4B).

In the example of FIG. 4C, but also relevant to other embodiments discussed herein, flanges 410 may be provided in the sleeves to provide gas tight connections to other components of the system. Additionally, o-rings (e.g., O ring 412) may be used along with such flanges. Further, a waveguide may be operably coupled 414 with the chamber, which may occur between flanges. Microwave energy is introduced into the chamber at 414 to ignite the gas to form the plasma 108. As with other embodiments, the plasma chamber may comprise an inner dielectric portion and an outer sleeve, with the inner portion proximate plasma ignition and extending along some length of the chamber.

The channels in the example of FIGS. 4A and 4B are provided by quartz tubes of the same material as the plasma chamber 116. The quenching channels 124 may form a gas-tight seal with the sidewalls of the plasma chamber 116 to maintain a pressure within the plasma chamber and without allowing gas to escape from the chamber. Regardless of the orientation of the quenching channels 124, the injected quenching gas may cool the plasma 108 within the plasma chamber 116 to increase the efficiency of the plasma reactor system 100. Returning to the method 200 of FIG. 2, the oxidized nitrogenous product from the plasma reaction after quenching may be removed for further processing and capture at operation 210.

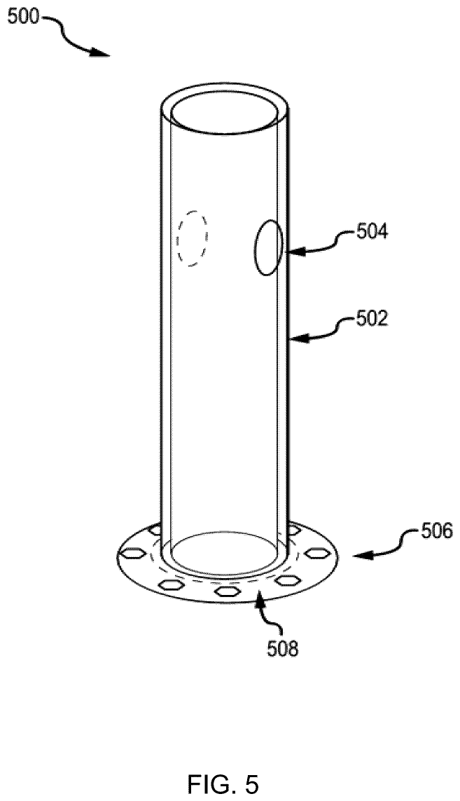

The plasma reactor system 100 may include, in some instances, an outer sleeve surrounding the plasma chamber 116 to provide structural support to the plasma chamber for maintaining an internal pressure within the chamber. FIG. 5 is a diagram illustrating a first outer sleeve 502 for a plasma chamber 116 of the plasma reactor system 100. In general, the outer sleeve 502 may be cylindrically-shaped similar to that of the plasma chamber 116, with a slightly larger diameter than the plasma chamber such that the plasma chamber may fit within the outer sleeve. In some instances, the outer sleeve 502 may be of a metal material, although other materials may be used. In some specific examples, the outer sleeve 502 may comprise stainless steel, aluminum, copper, carbon steel, hastalloy, and the like. As shown in the cross-section view of FIG. 1, an air gap 126 may be formed between the outer sleeve 502 and the plasma chamber 116. The air gap 126 may provide room for the plasma chamber 116 to expand from the high temperatures occurring within the chamber while also providing outward support to the walls of the plasma chamber such that a pressure may be maintained within the chamber. Higher concentrations of a conversion of the nitrogen 110 and oxygen 112 gas into the combination of ionized nitrogen and oxygen species may occur at higher pressures, aided by the structural support of the outer sleeve 502.

Returning to FIG. 5, one or more quench ports 504 may be located through the outer sleeve 502. The quench ports 504 allow for a tube, hose or other structure providing the quench channels 124 discussed above to pass through the outer sleeve 502 and into the plasma chamber 116. In some instances, the quench channels 124 may form a gas-tight seal with the quench ports 504. The outer sleeve 502 may also include a gas-tight connector 506 to connecting to and/or mounting on the outlet collar 120 of the plasma reactor system 100. One or more screws may tighten the gas-tight connector 506 of the outer sleeve 502 to the outlet collar 120. The gas-tight connector 506 may also include a gasket groove 508 on a bottom surface of the connector 506 for accepting an o-ring gasket to seal the outer sleeve 502 to the outlet collar 120.

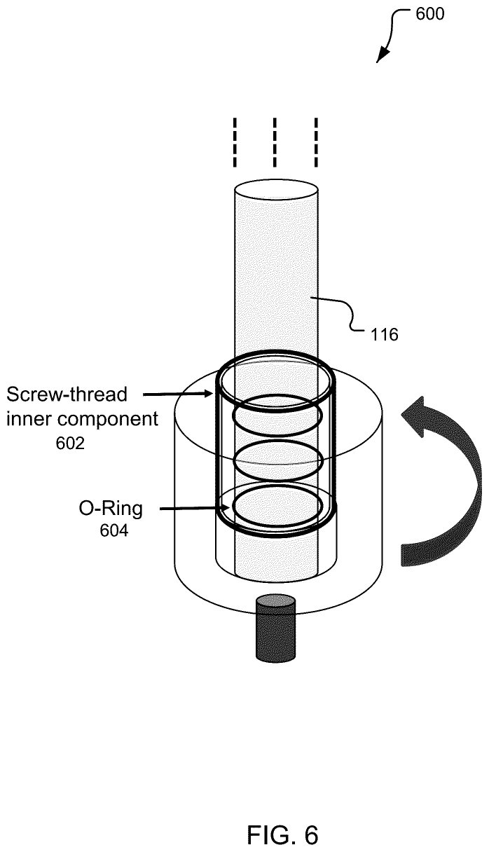

FIG. 6 is a diagram illustrating a second example of an outer sleeve 600 for the plasma reactor system 100. The outer sleeve of FIG. 6 may include a threaded inner portion 602 that engages and tightens the outer sleeve to a corresponding threaded portion of the reactor chamber 116 to support the reactor chamber under high temperatures and pressures. In addition, and also possible with the example of FIG. 5, one or more o-rings 604 may be oriented between the outer wall or surface of the plasma chamber and an inner wall or surface of the sleeve. The o-rings fill in the gap 126 and provide additional support to reduce cycling flexing of the plasma chamber. Rotation of the screw-thread inner portion 602 about the chamber 116 may tighten the outer sleeve against the o-rings 604 and apply an outer pressure to the reactor chamber. The tightening of the o-rings 604 to the reactor chamber 116 may provide support to the chamber and aid in maintaining a pressure within the chamber that is conducive to efficient fixed nitrogen generation.

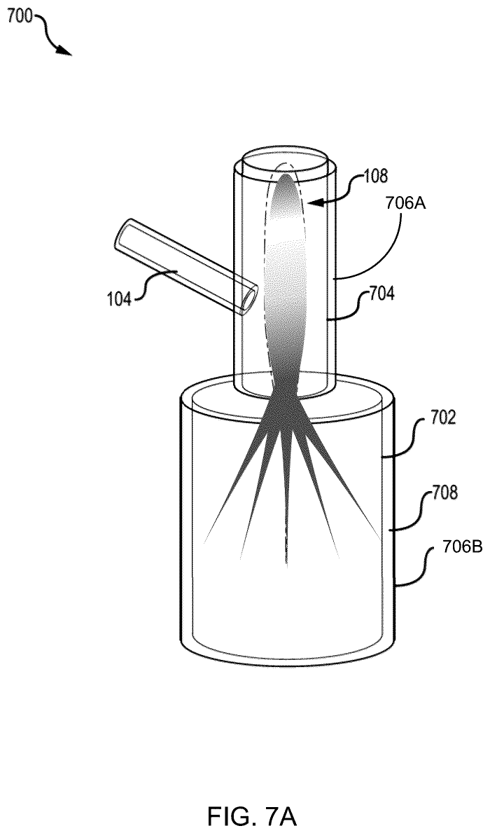

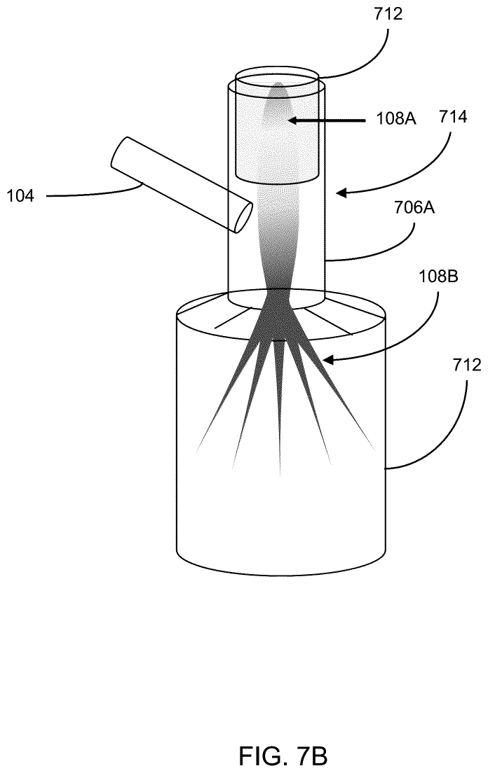

Additional quenching mechanisms may be included with the plasma reactor system 100. For example, FIG. 7A illustrates a plasma chamber 700 of the plasma reactor system 100 including an expansion portion 702 to quench fixed nitrogen products from a generated hot plasma 108. The plasma chamber 700 of FIG. 7A may be used in conjunction with the embodiments and implementations of the plasma reactor system 100 described above. In particular, the plasma chamber 700 may include an upper region 704 that is similar to the plasma chamber 116 described above with reference to FIG. 1. The upper portion 704 may include one or more quenching mechanisms 104, such as a quenching channel for introducing quenching gases into the upper chamber 704. To further quench the plasma 108 (and reduce the temperature of the plasma), the plasma chamber 700 may include a lower, expansion portion 702. In general, the expansion portion 702 has a larger diameter than the upper portion 704, but may otherwise may constructed from the same dielectric material (e.g., quartz) as the upper portion. As should be appreciated, the pressure within the expansion portion 702 of the chamber 700 may be less than that in the upper portion 704 due to the increase in volume of the expansion portion. As the temperature of the plasma 108 may be correlated to the pressure within the chamber 700, a quenching effect on the temperature of the plasma may occur within the expansion portion 702 as the volume within the chamber increases. Stated differently, as the plasma is injected into the higher volume area, the pressure decreases, and the temperature correspondingly decreases thereby cooling the plasma. This reduction in temperature of the plasma 108 within the expansion portion 702 may aid in quenching the plasma in a similar manner as injecting the quenching gas into the chamber through the quenching channel 104. The plasma chamber 700 of FIG. 7 may include a corresponding outer sleeve 706 as discussed above that has a similar shape as the inner, dielectric plasma chamber. Thus, the outer sleeve 706 may include an expansion portion or may be formed from a distinct larger diameter sleeve corresponding to the expansion portion 702 of the plasma chamber 700 to maintain the air gap 708 between the dielectric chamber and the outer sleeve. The expansion portion 702 may or may not be used with the quenching channel 104 to rapidly cool the plasma 108 generated within the chamber.

FIG. 7B illustrates a plasma chamber 710 of the plasma reactor system 100 including an expansion portion 712 to quench fixed nitrogen products from a generated hot plasma 108. The plasma chamber 710 of FIG. 7B may be used in conjunction with the embodiments and implementations of the plasma reactor system 100 described above. In particular, the plasma chamber 710 may include an upper region 714. Here, the upper region is at where the plasma is first ignited by the microwave system. The upper portion 714, includes a dielectric portion 712, which may be a sleeve, at the input to the upper relatively smaller diameter portion of the chamber with the remaining portion of the chamber defined by the outer sleeve 706A. Here, the internal dielectric portion does not extend the full extent of the upper chamber or more generally the entirety of the chamber noting that the lower, greater diameter, expansion portion 712 does not include an internal dielectric. Other chambers discussed herein may similarly include an internal dielectric chamber portion proximate where the microwave energy is introduced, and the plasma ignited with the remaining portion of the chamber being a stainless steel or other chamber material.

As with other embodiments, one or more quenching channels may introduce quench gas into the chamber at some location along its length and in some orientation. Similarly, injection gases may be provided to form a plasma vortex. The lower expansion chamber may alone, or in combination with quench gas, facilitate rapid cooling of the plasma 108B as it expands into the higher volume area of the expansion chamber to limit back reactions.

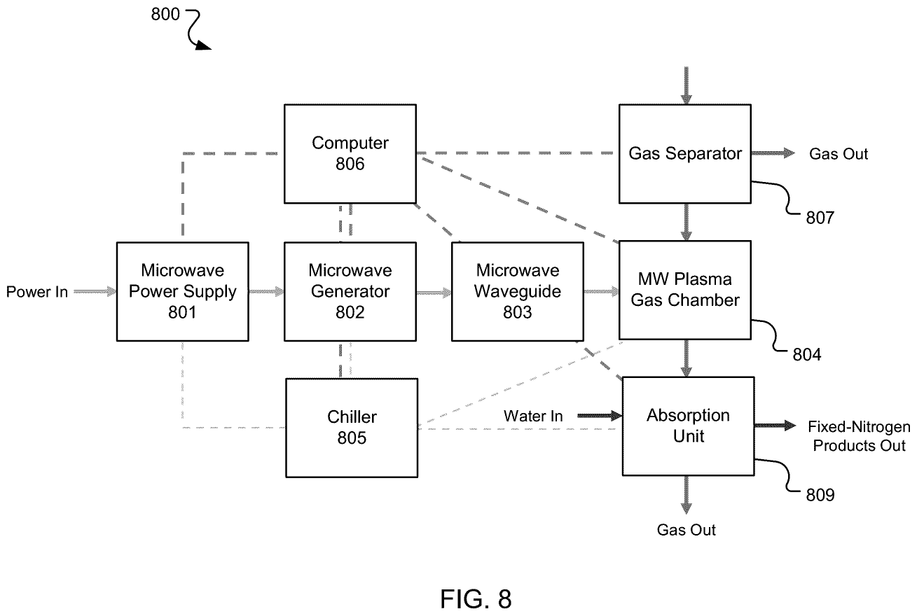

As mentioned above, the plasma reactor system 100 including the vortex flow assembly 102 and the quenching assembly 104 may be used with a microwave generator. FIG. 8 illustrates one such microwave-based plasma reactor system 800 in which the gas-flow engineered components and systems described herein may be utilized. In the system 800 of FIG. 8, a microwave generator 802 is connected to a MW- (microwave-) plasma-gas chamber 804 by a microwave waveguide 803. The microwave generator 802 may receive power from a microwave power supply 801. A microwave waveguide 803 is designed to contain and propagate microwaves to the MW-plasma-gas chamber 804 and to minimize reflected power. A microwave waveguide 803 may contain components to tune, concentrate the microwave field, or propagate surface waves into a well-controlled gas plasma, such as a 3-stub tuner and a surfa-guide launcher (tapered waveguide before plasma container). As used herein, a “well-controlled gas plasma” refers to a gas plasma having at least a minimum vortex flow measured in Ipm per diameter of the plasma tube. In some embodiments, a tuner may be automated to accept variable input power and adjust to variations in input power.

One or more of a MW-plasma-gas chamber 804 may contain a region where gas can be excited to form a plasma state. The plasma reactor 106 of FIG. 1 is one example of such a MW-plasma-gas chamber 804. This region may be designed to experience a strong electric field from microwave waveguide 803 and to withstand intense temperatures (on the order of hundreds or thousands of degrees) once the plasma is ignited. The strength of the electric field may be measured via electromagnetic field sensors or indirectly by measuring other features (e.g., power, plasma size, etc.). The electric field is typically strongest at the center of the longest dimension of the waveguide (i.e., where the plasma tube 116 is located). A strong electric field may be used to indicate a concentrated microwave field. A concentrated microwave field may be created by providing a waveguide having a hole in its path to allow microwaves to interface with a cross-section of gas, wherein the gas flows perpendicular to the waveguide orientation.

The region of plasma generation may be designed to be isolated from the cavity of the microwave waveguide by a dielectric barrier containing the gas. In some embodiments, one or more of a chiller 805 may be connected to any of the components in the microwave plasma system to provide active cooling either to protect system components from damage and/or to increase system efficiency as described in some cases below. Computer 806 may be used to control, operate, and coordinate the functions of subcomponents, valves, and sensors in the microwave plasma system and is also described in further detail below. In one embodiment, gas input into the system may be air pumped through gas separator 807 and into the gas flow region of MW-plasma-gas chamber 804. Gas separator 807 may change the composition of gas flowing into chamber 804 for plasma ionization. In some embodiments the initial gas composition of the gas feed to chamber 804 may contain over 5% oxygen and over 5% nitrogen, with a preferable range of 15-85% oxygen and 15-85% nitrogen, and a more preferable range of 50-80% oxygen and 20-50% nitrogen.

While not illustrated in FIG. 8, the system may further include an oxidation chamber and scrubber unit. The oxidized nitrogen species may be carried in the gas phase to an oxidation chamber where partially oxidized nitrogen species can be converted to further oxidized nitrogen species within the system. Particularly, nitric oxide, which has low solubility in water, is converted to nitrogen dioxide, which has high solubility and readily converts to nitric acid in water. In some implementations, gas from the oxidation chamber may be cooled in a heat exchanger before being directed toward an absorber unit that absorbs oxidized nitrogen species in the liquid form. In one example implementation, this absorber unit contains water that is used to convert nitrogen dioxide into nitric acid as a product. In another example implementation, the absorber unit may contain a salt or basic compound, such as potassium chloride, potassium hydroxide, sodium carbonate, calcium carbonate, calcium hydroxide, or phosphate rock, among others, to produce nitrate salts as a product. These features, among others, may be used, alone or in various combinations, in a microwave plasma system to efficiently produce nitric acid, nitrate salts, and more generally nitrate-based fertilizers. After such products are formed, a system may include various devices to concentrate or dry them such as distillation and a rotary drying drum.

A scrubber unit, which may scrub NOx (NO, NO₂, N₂O, or other NₓO_{y} chemicals) or acidic (HNO3, HONO) components from a waste gas stream (e.g., a stream from the absorption unit). The further processing of the waste gas stream may be for protecting the environment, and the scrubber may be in the form of a catalytic converter or liquid reactor to capture and remove the NOx or acidic components. In some embodiments, the scrubber may use selective catalytic reduction (SCR) to remove the NOx. In other embodiments, a scrubber may be an alkaline chemical scrubber.

In other embodiments air may be used directly. Without wishing to be bound by theory, air may be favorable because it may not require further purification; however, using air may introduce impurities or may decrease efficiency. For example, CO₂ in air may coat the plasma chamber with conductive carbon over time and may need to be filtered out. In additional embodiments, argon may be added to the initial gas composition because argon readily ignites and sustains a plasma. In some embodiments, additional gas separators may provide other gases to other components in the microwave system or may recirculate gases from product streams to reactant streams. Gases recirculated from product streams to reactant streams may be performed to improve cost effectiveness, to increase oxidation of reactants, to improve purity of product streams, or to destroy products harmful to the environment. In some embodiments, the gases recirculated from product streams to reactant streams may include argon, nitrogen, oxygen, N₂O, and ozone. In some aspects, the product gases may be recirculated after cooling to protect gas separation equipment from excess heat.

In certain embodiments, MW-plasma-gas chamber 804 contains a plasma which converts an amount of nitrogen and oxygen from the gas input system into oxidized nitrogen species. This conversion rate may be between 0-10% or more of the gas input. In some aspects, the conversion may be 0-1%, 1-2%, 2-3%, 3-4%, 4-5%, 5-6%, 6-7%, 7-8%, 8-9%, or 9-10%. In still further aspects, the conversion may be 0-2%, 0-3%, 0-4%, 0-5%, 0-6%, 0-7%, 0-8%, 0-9%, 1-10%, 2-10%, 3-10%, 4-10%, 5-10%, 6-10%, 7-10%, or 8-10%.

In certain embodiments an absorption unit 809 may be fluidically connected to receive the oxidized nitrogen species containing nitrogen dioxide. In many embodiments, an absorption unit 809 contains at least water. Water may react with nitrogen dioxide to form nitrates in solution. Absorber 809 may be designed to intake water as an absorber and output aqueous fixed-nitrogen products. The fixed nitrogen products may contain nitric acid or other nitrate-based fertilizers. In some embodiments, the absorber unit may be one or more of bubble-absorber columns, plate-absorber columns, liquid-shower columns, or a combination of these.

In some embodiments, the fraction of nitric oxide in the oxidized nitrogen species may be about 40% to about 80% by volume. In some additional embodiments, the fraction of nitric oxide in the oxidized nitrogen species may be about 40% to about 45%, about 45% to about 50%, about 50% to about 55%, about 55% to about 60%, about 65% to about 70%, about 70% to about 75%, or about 75% to about 80% by volume. In still further embodiments, the fraction of nitric oxide in the oxidized nitrogen species may be about 40% to about 50%, about 40% to about 55%, about 40% to about 60%, about 40% to about 65%, about 40% to about 70%, about 40% to about 75%, about 45% to about 80%, about 50% to about 80%, about 55% to about 80%, about 60% to about 80%, about 65% to about 80%, or about 70% to about 80% by volume. In still further embodiments, the fraction of nitric oxide in the oxidized nitrogen species may be about 40%, 45%, 50%, 55%, 60%, 65%, 70%, 75%, or about 80% by volume.

In some embodiments, nitric acid may be captured from the product stream with an efficiency of greater than about 80%. In some additional embodiments, nitric acid may be captured from the product stream with an efficiency of about 80% to about 85%, about 85% to about 90%, about 90% to about 95%, or about 95% to about 99.9%. In further embodiments, nitric acid may be captured from the product stream with an efficiency of about 80% to about 90%, about 80% to about 95%, about 80% to about 99.9%, about 85% to about 99.9%, about 90% to about 99.9%, or about 95% to about 99.9%. In still further embodiments, the nitric acid may be captured from the product stream with an efficiency of about 80%, 81%, 82%, 83%, 84%, 85%, 86%, 87%, 88%, 89%, 90%, 91%, 92%, 93%, 94%, 95%, 96%, 97%, 98%, 99%, or about 99.9%.

The efficiency of producing oxidized nitrogen species may be described as the level of plasma energy consumed per pound of nitrogen supplied (kWh/lb N). In some embodiments, the efficiency of producing oxidized nitrogen species may be less than about 20 kWh/lb N. In some embodiments, the efficiency of producing oxidized nitrogen species may be less than about 20 kWh/lb N, less than about 15 kWh/lb N, less than about 10 kWh/lb N, or less than about 5 kWh/lb N. In some additional embodiments, the efficiency of producing oxidized nitrogen species may be about 15 kWh/lb N, about 14 kWh/lb N, about 13 kWh/lb N, about 12 kWh/lb N, about 11 kWh/lb N, about 10 kWh/lb N, about 9 kWh/lb N, about 8 kWh/lb N, about 7 kWh/lb N, about 6 kWh/lb N, about 5 kWh/lb N, or less than about 5 kWh/lb N.

The efficiency of producing oxidized nitrogen species may also be considered in the context of producing nitrate fertilizers. In some embodiments, the efficiency of producing nitrate fertilizers using the process of the present disclosure may be about 5 kWh/lb N to about 25 kWh/lb N. In some additional embodiments, the efficiency of producing nitrate fertilizers using the process of the present disclosure may be about 5 kWh/lb N to about 10 kWh/lb N, about 10 kWh/lb N to about 15 kWh/lb N, about 15 kWh/lb N to about 20 kWh/lb N, or about 20 kWh/lb N to about 25 kWh/lb N. In further embodiments, the efficiency of producing nitrate fertilizers using the process of the present disclosure may be about 5 kWh/lb N to about 15 kWh/lb N, about 5 kWh/lb N to about 20 kWh/lb N, about 10 kWh/lb N to about 25 kWh/lb N, or about 15 kWh/lb N to about 25 kWh/lb N. In still further embodiments, the efficiency of producing nitrate fertilizers using the process of the present disclosure may be about 5 kWh/lb N, 6 kWh/lb N, 7 kWh/lb N, 8 kWh/lb N, 9 kWh/lb N, 10 kWh/lb N, 11 kWh/lb N, 12 kWh/lb N, 13 kWh/lb N, 14 kWh/lb N, 15 kWh/lb N, 16 kWh/lb N, 17 kWh/lb N, 18 kWh/lb N, 19 kWh/lb N, 20 kWh/lb N, 21 kWh/lb N, 22 kWh/lb N, 23 kWh/lb N, 24 kWh/lb N, or about 25 kWh/lb N.

Through the systems and methods described herein, a more efficient microwave-based plasma reaction may be obtained. FIG. 9 illustrate graphs of the effect of vortex angle on efficiency and a total nitrogen concentration of the plasma reactor system 100 at various air flow rates measured in standard liter per minute (SLPM). In particular, graph 902 illustrates a measured efficiency 908 for a range of vortex angles 906 of the directional channels of the gas vortex input mechanism 102 and at various air flow rates. Graph 904 illustrates produced oxide nitrogen (NOx) 910 for a range of vortex angle 906 of the directional channels of the gas vortex input mechanism 102 and at various air flow rates. In the particular instance illustrated, a fixed microwave input power of 700 Watts is provided to microwave plasma system. The experimental results indicate that NOx conversion efficiencies 908 as well as total NOx concentration 910 improves with increasing vortex angle 906 from 7 to 75 degrees. At low vortex angles efficient nitrogen fixation is challenging, however, at high vortex angles, the plasma may become unstable and challenging to maintain due to excessive turbulence and viscosity of the flow. Another important process variable which may influence the efficiencies and total NOx concentration is air flow rate. Higher air flow rates generally improves the efficiency, whereas the NOx concentration decreases. The experimental results illustrated in FIG. 9 show that best NOx conversion efficiencies can be obtained at higher NOx concentration by optimizing air flow and vortex nozzle angle.

It is to be understood that this invention is not limited to the particular example apparatuses, methods, compositions, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly and synonymously “in one example”, “in one instance”, or “in one aspect” in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims, or can be learned by the practice of the principles set forth herein.

What is claimed is:

1. A microwave-plasma reactor for generating fixed-nitrogen products comprising:
a microwave generator operably coupled to a plasma chamber; and
a gas-vortex-generating component operably coupled with the chamber comprising one or more directional channels to direct input gas in a rotational motion into the gas chamber to generate a gaseous vortex within the gas chamber.

2. The microwave-plasma reactor according to claim 1, where the gas-vortex-generating component comprises two or more opposing inputs, each with groove channels comprising a pitch angle between 15 degrees and 65 degrees from a top of the gas-vortex-generating component.

3. The microwave-plasma reactor according to claim 1, wherein the gas-vortex-generating component directional channels are adjacent to an outer surface of the gas-vortex-generating component.

4. The microwave-plasma reactor according to claim 1, wherein the gas-vortex-generating component directional channels are adjacent to an inner surface of the gas-vortex-generating component.

5. The microwave-plasma reactor according to claim 1, wherein the input gas comprises nitrogen and oxygen and the gas chamber outputs fixed nitrogen gaseous products from the plasma.

6. The microwave-plasma reactor according to claim 1, wherein the gas-vortex-generating component is a cylindrically-shaped collar for connecting to the gas chamber.

7. The microwave-plasma reactor according to claim 1 further comprising:
a quench channel operably coupled with the plasma chamber, the quench channel providing quench fluid into the plasma chamber to cool the plasma.

8. A microwave-plasma reactor for generating fixed-nitrogen products comprising:
a microwave generator operably coupled with a plasma chamber;
a gas-vortex-generating component connected to the plasma chamber comprising one or more directional channels to direct input gas in a rotational motion into the plasma chamber to generate a gaseous vortex within the gas chamber wherein microwave energy ignites a plasma from the gaseous vortex; and
one or more quenching ports operably coupled with the gas chamber to provide a cooling stream of gas to quench reactions generated by the plasma.

9. The microwave-plasma reactor according to claim 8, wherein the one or more quenching ports are positioned to inject a cooling stream at or proceeding a point of plasma ignition in the plasma chamber.

10. The microwave-plasma reactor according to claim 8, wherein the one or more quenching ports comprises two or more opposing quenching ports in a sidewall of the plasma chamber.

11. The microwave-plasma reactor according to claim 10, wherein the opposing one or more quenching ports are configured at an angle between 10 degrees and 170 degrees with an axis of the plasma chamber.

12. The microwave-plasma reactor according to claim 10, wherein the one or more opposing quenching ports are laterally offset to generate a vortex of quenching gases within the plasma chamber.

13. The microwave-plasma reactor according to claim 8, wherein the one or more quenching ports are configured to generate a vortex concurrent to the swirling motion generated by the gas-vortex-generating component.

14. The microwave-plasma reactor according to claim 8, wherein the one or more quenching ports are configured to generate a vortex countercurrent to the swirling motion generated by the gas-vortex-generating component.

15. The microwave-plasma reactor according to claim 8, wherein the gas chamber comprises a reactor portion with a first diameter and a quenching portion with a second diameter larger than the first diameter.

16. The microwave-plasma reactor according to claim 8 further comprising:
a metal sleeve surrounding the gas chamber and comprising sleeve quenching ports positioned in a sidewall of the metal sleeve corresponding to the quenching ports of the gas chamber, the metal sleeve defining an air gap between an outer surface of the gas chamber and an inner surface of the metal sleeve.

17. A method for producing fixed-nitrogen products by microwave plasma oxidation of nitrogen, the method comprising:
producing a microwave plasma in a plasma reactor containing a gas stream comprising nitrogen and oxygen;
producing a rotational gas stream along a wall of the plasma reactor;
producing oxidized nitrogenous species in the plasma reactor with the microwave plasma through a conversion of the nitrogen and the oxygen; and
quenching the oxidized nitrogenous species in the plasma reactor using a cooling stream.

18. The method of claim 17 wherein the rotational gas stream is injected in a rotational pattern along a cylindrical wall of the plasma reactor.

19. The method of claim 17, wherein the oxidized nitrogenous species comprises nitric oxide, nitrogen dioxide, nitrous oxide, dinitrogen dioxide, nitric acid, and nitrous acid.

20. The method of claim 17, wherein the conversion of the nitrogen in the gas stream to the oxidized nitrogenous species is between about 0% to about 10%.

21. The method of claim 17, wherein a concentration of nitrogen in the gas stream is between about 5% to about 85% and wherein a concentration of oxygen in the gas stream is between about 5% to about 85%.

22. The method of claim 17, wherein the cooling stream comprises a high-velocity gas surrounding a high-turbulent viscosity gas.

23. The method of claim 17, wherein the cooling stream comprises a gas with a different composition than the gas stream.

24. The method of claim 23, wherein the cooling stream further comprises an oxygen-rich gas stream to quench and further oxidize the oxidized nitrogenous species.

25. The method of claim 17, further comprising wherein the cooling stream comprises a quenching liquid.

26. The method of claim 17, wherein a fraction of nitric oxide of the oxidized nitrogenous species is between about 40% to about 80% by volume.

27. The method of claim 17, wherein the gas stream further comprises air.

28. The method of claim 17, wherein the gas stream further comprises argon.

29. The method of claim 17 wherein the cooling stream is injected to cooperate with a plasma vortex comprising the oxidized nitrogenous species.

30. The method of claim 17 wherein the cooling stream is injected counter to a plasma vortex comprising the oxidized nitrogenous species.

31. The method of claim 18 wherein an increase in a production of the oxidized nitrogenous species in the plasma reactor correlates to an increase of an injection angle of the rotational gas-stream within a range of about 7 degrees to 75 degrees.

32. The method of claim 18 wherein an increase in an efficiency of the plasma reactor correlates to an increase of an injection angle of the rotational gas-stream within a range of about 7 degrees to 75 degrees.
